(19) United States
(12) Patent Application Publication
(10) Pub. No.: US 2020/0111872 A1
(43) Pub. Date: Apr. 9, 2020

(54) STRUCTURE WITH SUPERIMPOSED SEMICONDUCTOR BARS HAVING A UNIFORM SEMICONDUCTOR CASING

(71) Applicant: Commissariat A L'Energie Atomique et aux Energies Alternatives, Paris (FR)

(72) Inventors: Shay REBOH, Grenoble Cedex 09 (FR); Remi Coquand, Grenoble Cedex 09 (FR)

(73) Assignee: Commissariat A L'Energie Atomique et aux Energies Alternatives, Paris (FR)

(21) Appl. No.: 16/590,557

(22) Filed: Oct. 2, 2019

(30) Foreign Application Priority Data
Oct. 5, 2018 (FR) 18 59238

(51) Int. Cl. H01L 29/10; H01L 29/66

(52) U.S. Cl. CPC H01L 29/1033; H01L 29/66545

(57) ABSTRACT

Production of a structure for a transistor, with semiconductor bars disposed one above the other and able to form at least one transistor channel region, the method comprising growth of a semiconductor material around semiconductor bars disposed one above the other, while, during this growth, preserving a dummy bar situated above the semiconductor bars in order to limit the thickness of semiconductor material formed and/or to make this thickness uniform from one bar to another.

### TECHNICAL FIELD AND PRIOR ART

The present invention relates to the field of microelectronics and transistors, and relates more particularly to the field of transistors provided with a structure forming at least one channel in the form of a plurality of semiconductor bars disposed one above the other.

To allow electrostatic control of the transistor hannel, such a structure is typically associated with a gate electrode with a so-called “enrobing” configuration, that is to say which extends all around the bars, both opposite their top and bottom faces, but also laterally. Such a configuration makes it possible in general terms to obtain better electrostatic control of the channel structure.

To improve the performances of a transistor with semiconductor bars disposed one above the other, it is possible to produce a channel structure having an elastic deformation or stress. For this purpose, prior to the formation of the gate, it is possible to grow, around the bars, a semiconductor material having a mesh parameter different from that of the bars. Such a material is typically produced by means of an epitaxial growth method.

However, it proves difficult to obtain a uniform thickness of material from one bar to another in the structure, in particular at a top part of the bars. The bar situated at the top of the structure may, on its top part, have a greater thickness of material than that formed on the top part of the underlying bars. Because of this, the chemical composition, the stress level and the electrical behaviour, in particular the threshold voltage and the electrostatic controlled by the gate of the channel, may differ from one bar to another in the channel structure.

The problem therefore lies in producing an improved structure for a transistor with superimposed semiconductor bars.

### DISCLOSURE OF THE INVENTION

An aspect of the present invention relates to the production of a structure for a transistor, with semiconductor bars disposed one above the other and able to form at least one channel region of the transistor, with a semiconductor material around the bars, the thickness of semiconductor material formed around the bars being substantially similar from one bar to another.

In order to product such a structure, a method is in particular provided comprising growth of a semiconductor material around the semiconductor bars disposed one above the other, while keeping during this growth a dummy bar situated above the semiconductor bars in order to make the growth conditions equivalent from one bar to another, and to be able to obtain similar deposits from one bar to another.

An embodiment provides a method comprising the following steps:

a) providing, on a support, a stack comprising an alternation of one or more first bars made from sacrificial material, in particular a first semiconductor material, and one or more second bars based on a second semiconductor material, said stack being covered with a so-called “dummy” bar made from a given material, the dummy bar being arranged on, and typically in contact with, a given bar among said first bars, said given bar being disposed at the top of said stack,

b) forming a masking with an opening revealing portions referred to as “central portions” of said bars in said stack covered with a portion referred to as the “central portion” of said dummy bar,

c) removing in the opening the central portion of the first bars by selective etching of the sacrificial material vis-à-vis said second semiconductor material and the given material of said dummy bar, then

d) growing a semiconductor material around the second bars while during this growth keeping said central portion of said dummy bar.

The growth carried out at step d) may in particular be implemented by means of a selective epitaxy method.

During the growth at step d), because of the presence of the dummy bar, the bar based on the second semiconductor material which is situated at the top of the superimposition is protected by the dummy bar. The other underlying bars are themselves protected by one or more bars situated above them.

Such an arrangement can in this way make it possible to obtain at step d) thicknesses of semiconductor material on the bar at the top that are substantially equal or close to the thicknesses of semiconductor material formed on the other bars. In particular, the thickness of semiconductor material formed on a top face of the top bar is substantially equal to that formed on the top face of the bars situated below.

The semiconductor material covering a portion of the second semiconductor bars is able to form at least one transistor channel region. Thus, the method may further comprise, after step d), the formation of a gate around the second semiconductor bars covered by said semiconductor material.

The dummy bar may be formed by means of a material different from the sacrificial semiconductor material and the second semiconductor material.

One embodiment provides the first semiconductor material based on SiGe, the second semiconductor material being silicon.

The dummy bar is advantageously made from an insulating material, preferably amorphous.

The dummy bar may in particular be provided in an insulating material with a composition similar to the material from which the insulating spacers are made.

A particular example embodiment provides a dummy bar made from SiN or SiBCN.

According to a particular embodiment of the method, the dummy bar may serve as an etching mask when etching is carried out, prior to step a) or during step a), on a stack of semiconductor layers in order to form said stack of bars.

The dummy bar typically has dimensions, in particular a width, similar to the dimensions, in particular the width, of the second bars.

Advantageously, the semiconductor material that is grown on the second bars has a mesh parameter different from that of the second semiconductor material. This can make it possible to obtain a stressed channel structure.

The semiconductor material that is grown may in particular be based on germanium, in particular when the second bars are made from silicon.

In this case, the method may further comprise, after growth of the semiconductor material on the second bars, at least one thermal annealing so as to diffuse germanium in the second bars.

It is also possible to keep a thickness of semiconductor material around the second bars, and then to form a gate on regions of semiconductor material preserved around the second bars.

According to a particular embodiment, the masking step b) may be formed by insulating spacers and an encapsulation layer situated on either side of an assembly formed by a sacrificial gate and the insulating spacers, the opening for its part being formed by removal of the sacrificial gate arranged between the insulating spacers.

The method may further comprise, prior to the formation of the opening, steps of:
production of a sacrificial gate on the stack,
formation of insulating spacers either side of the sacrificial gate,
removal of the stack on either side of the assembly formed by the sacrificial gate and the spacers,
selective removal of end portions of the first bars so as to reduce the length thereof and to release spaces on either side of end regions of the first bars,
formation of internal spacers made from dielectric material in said spaces.

The method may further comprise, after the formation of the internal spacers and prior to the formation of the opening, steps of:
formation of source and drain regions,
formation of at least one encapsulation layer on the source and drain regions, the encapsulation layer being arranged so as to reveal the sacrificial gate.

After the selective etching steps c) and prior to the step d) of growth of semiconductor material on the second bars, the method may further comprise at least one step of thinning the central portion of the second bars.

In this case, when the central portion of the second bars is thinned by a given thickness during said thinning, the semiconductor material formed by growth on the second bars may be provided with a height substantially equal to the given thickness.

### BRIEF DESCRIPTION OF THE DRAWINGS

The present invention will be understood better from a reading of the description of example embodiments given, purely indicatively and in no way limitatively, referring to the accompanying drawings, on which:

FIGS. 1A-1K serve to illustrate an example of a method for producing a structure of semiconductor bars disposed one above the other, an insulating bar being arranged on either side of the bars;

FIGS. 2A-2B serve to illustrate a variant embodiment.

Identical, similar or equivalent parts in the various figures bear the same numerical references so as to facilitate passage from one figure to another.

The various parts shown by the figures are not necessarily shown to a uniform scale in order to make the figures more legible.

Furthermore, in the following description, terms that are dependent on orientation, such as “on”, “above”, “top”, “bottom”, “lateral”, etc., of a structure apply on the assumption that the structure is oriented as illustrated in the figures.

The various parts shown in the figures are not necessarily shown to a uniform scale, in order to make the figures more legible.

### DETAILED DISCLOSURE OF PARTICULAR EMBODIMENTS

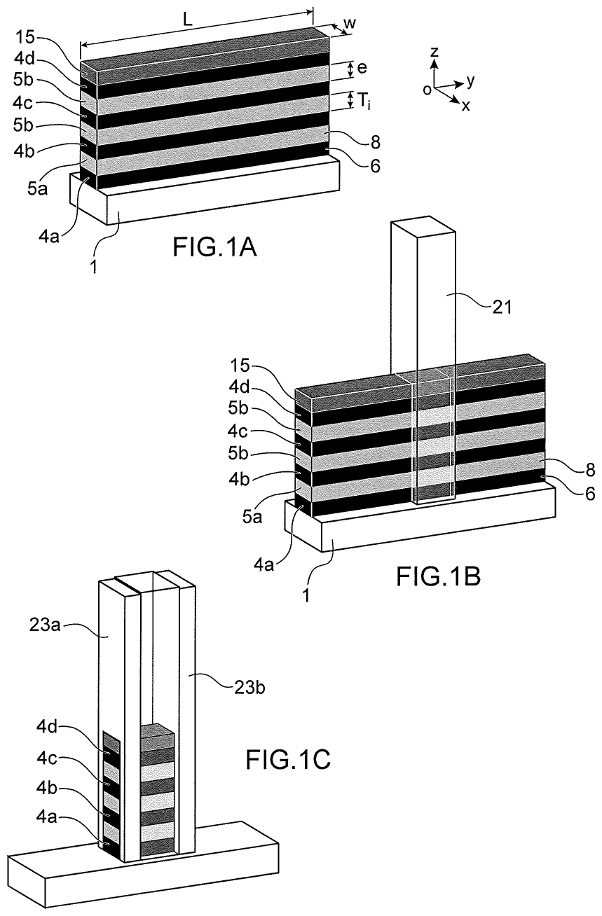

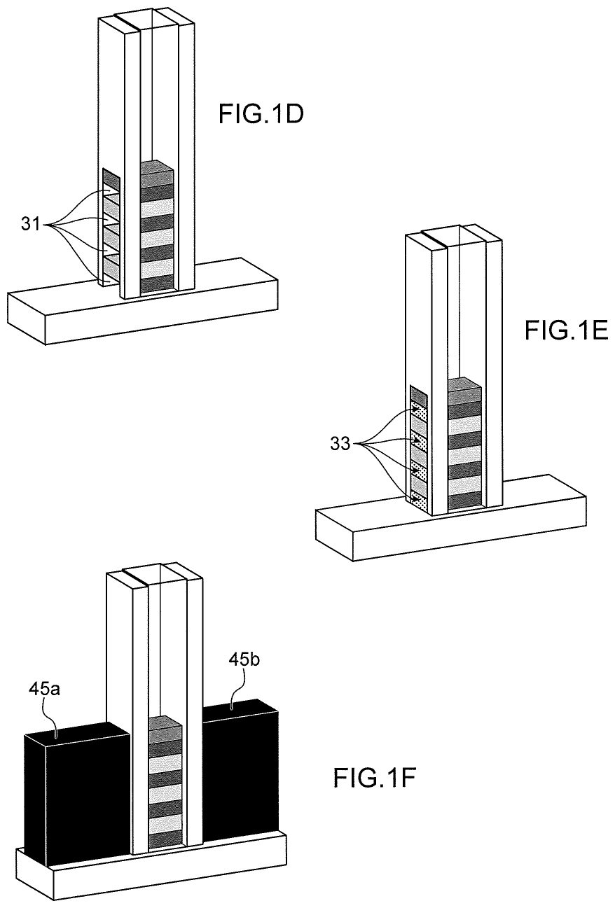

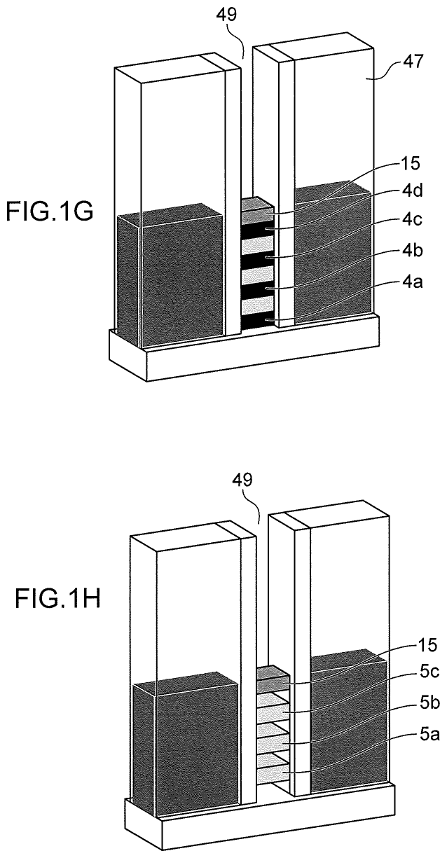

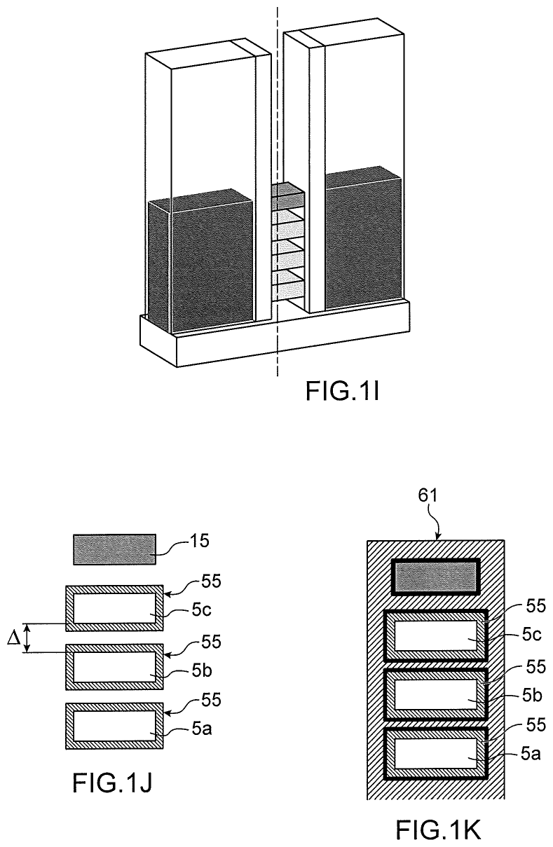

Reference is now made to FIG. 1A, giving an example of a semiconductor structure with superimposed semiconductor bars.

The structure may be formed from a substrate 1 of the type commonly referred to as “bulk”, formed by a semiconductor layer, or a substrate of the semiconductor on insulator type comprising a semiconductor support layer covered by an insulating layer for example based on SiO₂, itself covered with a thin surface semiconductor layer.

The semiconductor structure is typically produced from a semiconductor stack comprising an alternation of layers based on a first material 6, which may be a semiconductor, and layers based on a second material 8 that is a semiconductor and different from the first material 6. The first material 6 is able to be etched selectively vis-à-vis the second material 8. For example, the first material 6 is based on silicon germanium while the second material 8 is silicon. According to a particular example embodiment, the first material 6 is based on Si₁₋ₓGeₓ, with x for example between 0.2 and 0.4. Typically, such a stack is formed by successive epitaxies of semiconductor layers.

The structure shown in FIG. 1A is obtained at the end of an etching of the semiconductor layers, the etched layers typically comprising portions in the form of bars.

The structure thus comprises an alternation of bars 4a, 4b, 4c, 4d, based on the first material 6, and bars 5a, 5b, 5c based on the second material 8. The stacked bars 4a, 5a, 4b, 5b, 4c, 5c, 4d, which are referred to as either “nano-sheets” or “nano-wires” have for example a parallelepipedal or substantially parallelepipedal shape.

The first bars 4a, 4b, 4c, 4d have a so-called “central” portion, which is sacrificial, intended to be removed subsequently, while a so-called “central” portion of second bars 5a, 5b, 5c is based on the semiconductor material 8 and is intended to form a channel structure or a part of a channel structure or a structure giving mechanical support to a transistor channel structure.

At the top of a semiconductor stack, a bar 15 made from a given material different from the materials 6 of the first bars and 8 of the second bars, is also produced. The bar 15 is preferably made from a material suitable for resisting a selective etching of the first material 6. The bar 15 is termed “dummy” since, in this embodiment, unlike the bars 5a, 5b, 5c, is not designed to form the channel structure. The dummy bar 15 is typically produced from an insulating material, for example such as silicon nitride (SiN) or SiBCN. The bar 15 may be in contact with the top semiconductor bar 5c or be separated from this bar 5c by means of a layer for example of silicon oxide.

This dummy bar 15 may have the same dimensions and preferably at least the same width W, for example the same width W and the same length L, as the semiconductor bars 5a, 5b, 5c. W and L are here dimensions measured in directions parallel to the principal plane of the substrate and in particular respectively to the axis x and to the axis y of an orthogonal reference frame [O; x; y; z], the principal plane of the substrate for its part being a plane of the substrate defined in FIG. 1A as a plane passing through the substrate and parallel to the plane [O; x; y]. The bars 5a, 5b, 5c may have a width for example between 10 nm and 100 nm. The bars 5a, 5b, 5c may also have a thickness e (the dimension measured parallel to the axis z) typically between 4 nm and 12 nm, for example between 6 nm and 8 nm. The dummy bar 15 may advantageously fulfil the function of etching mask during the step of etching of the stack of semiconductor layers leading to the formation of the stack of bars 4a, 5a, 4b, 5b, 4c, 5c, 4d.

Next a sacrificial gate 21 (FIG. 1B) is produced, for example by forming at least a gate dielectric, for example of SiO₂, and a gate material, for example polysilicon, on the structure and the dummy bar 15.

So-called “external” insulating spacers 23a, 23b are produced on either side of the dummy gate 21. The insulating spacers 23a, 23b are for example based on silicon nitride (SiN) or SiCN. The insulating spacers 23a, 23b and the sacrificial gate 21 thus cover at least a central region of the stack of semiconductor bars.

Regions of the stack around the central region and which are situated on either side of the insulating spacers 23a, 23b are also removed (FIG. 1C). This removal is typically carried out by anisotropic etching.

It is next possible to form so-called “internal” insulating spacers. For this purpose, a selective etching of zones of the first bars 4a, 4b, 4c, 4d based on the material 6 that are situated at the ends of the bars 4a, 4b, 4c, 4d facing the external spacers 23a, 23b is first of all carried out. Removal of these zones makes it possible to create cavities 31 or spaces 31 (FIG. 1D). Next these spaces 31 are filled with a dielectric material 33, which may be a dielectric material of the so-called “low-k” type (with a low dielectric constant) and/or such as for example based on SiN, SiBCN or SiOCN.

It is then possible to carry out removal of a thickness of this dielectric material 33 in zones situated on either side of the set of spacers 23a, 23b. This removal is carried out in order to preserve regions of dielectric material 33 in line with ends of bars 4a, 4b, 4c, 4d. Etching can for example be carried out by means of a wet method based on phosphoric acid when the dielectric material 33 is based on SiN.

These regions of dielectric material 33, also referred to as “internal spacers”, are preferably, as in the example illustrated in FIG. 1E, aligned with the external spacers. Preferably, the internal spacers have an internal face, situated against the bars 4a, 4b, 4c, 4d, which is aligned with an internal face of the external spacers 23a, 23b, the internal face of the spacers being defined here as a face situated against the gate.

Next it is possible to form source and drain blocks 45a, 45b. These blocks may be produced for example by carrying out an epitaxial growth arising on at least a portion of the bars 5a, 5b, 5c of semiconductor material 8 (FIG. 1F).

Then a so-called “encapsulation” layer 47 is formed so as to cover the structure. The “encapsulation” layer 47 may for example be based on silicon oxide. A step of removal, for example by flattening or CMP polishing (CMP standing for “chemical mechanical planarization”), of a thickness of this encapsulation layer 47 can then be carried out with a stop so as to give access of the sacrificial gate 21 or to a hard mask arranged on the sacrificial gate that will next be removed in order to access the top or the upper face 7 of the sacrificial gate 21. Then an opening 49 is produced so as to once again reveal a central part of the stack of semiconductor bars (FIG. 1G). This opening 49 is formed by removing the sacrificial gate 21. When the sacrificial gate 21 is made from polysilicon, removal thereof can be carried out for example by wet etching by means of a solution based on ammonia, with a stop on the sacrificial gate dielectric, the latter next being able to be removed in the opening 49, for example by etching by means of hydrofluoric acid for the typical case of a dielectric based on silicon oxide.

Then the first material 6 is removed in the opening 49 (FIG. 1H). In particular selective etching of the first material 6 vis-à-vis the second material 8 is carried out. The etching is also advantageously selective vis-à-vis the material of the dummy bar 15. Central portions of the first bars 4a, 4b, 4c, 4d situated in the opening 49 are thus removed, while the dummy bar 15 is preserved. Preferably, the etching is also selective vis-à-vis the material or materials of the internal 33 and external 23a, 23b spacers. Selective removal can be carried out for example by vapour chemical etching, for example using HCl, when the bars 4a, 4b, 4c, 4d are based on silicon germanium, when the bars 5a, 5b, 5c are based on silicon, and when the dummy bar and the internal and external spacers are based on SiON, SiBCN.

In this way suspended bars 5a, 5b, 5c based on the semiconductor material 8, in this example silicon, are obtained in the opening 49. The bars 5a, 5b, 5c based on the semiconductor material 8 have a central portion that extends in the opening 49 and is not covered by another material, so that an empty space is formed around the central portion of the bars 5a, 5b, 5c based on semiconductor material 8.

After the step of removal of the first bars 4a, 4b, 4c, epitaxial growth of semiconductor material 55 is carried out around the second bars 5a, 5b, 5c. The semiconductor material 55 that is grown is typically provided with a mesh parameter different from that of the material of the second bars 5a, 5b, 5c, in particular in order to obtain a stressed channel structure. The semiconductor material 55 can be based on Si_{1-y}Ge_{y} when the second bars 5a, 5b, 5c are made from silicon, with for example a concentration of germanium of between 20% and 80% (0.2≤y≤0.8, in particular between 20% and 40% 0.3≤y≤0.4 when it is wished to subsequently preserve the semiconductor material 55 around the bars 5a, 5b, 5c.

One particularity of this step of forming the semiconductor material 55 is that the top of the bar 5c situated at the top of the superimposition of bars 5a, 5b, 5c is protected by means of the dummy bar 15. The bar 5c protected by the dummy bar 15 is thus placed under conditions of exposure to the deposition of methods similar to those in which the underlying bars 5b, 5c are during growth. This makes it possible to obtain a growth of material 5c that is equivalent or close from one bar to another. The bar 5c situated at the top of the staged semiconductor structure can thus be covered, on its top face, with a thickness of semiconductor material 55 substantially equal to the one covering a corresponding top face of the other bars 5a, 5b (FIG. 1J, giving a view in cross-section of a central part of the structure).

However, a layer of semiconductor material 55 with a thickness less than half of the distance A between adjacent bars 5a-5b, 5b-5c is advantageously provided, this distance A typically corresponding to the thickness of the first bars 4a, 4b, 4c, 4d that was removed in the opening 49.

It is next possible to form a gate electrode 61 on such a structure, keeping around the bars 5a, 5b, 5c a thickness of semiconductor 55, and thus preserving an arrangement of the core-shell type with the second bars 5a, 5b, 5c forming a core of semiconductor material 8 surrounded by the semiconductor 55 forming a shell with a different composition, in particular designed to be stressed.

Production of the gate typically comprises the deposition of at least one gate dielectric, for example a stack of SiO₂ and HfO₂, then at least one gate material, for example a stack of TiN and W around the second bars 5a, 5b, 5c (FIG. 1K). According to a variant embodiment, before forming the gate 61, in particular when the semiconductor material 55 is based on Si_{1-y}Ge_{y}, the germanium can be diffused with this material 55 in second bars 5a, 5b, 5c and thus enrich them with germanium.

For this purpose, one or more thermal annealings can be carried out. For example, it is possible to perform at least one thermal annealing at a temperature that may be between 900° C. and 1100° C. for a period that may be between 5 seconds and 40 seconds. The duration and temperature of the thermal annealing are dependent on the thickness and concentration of germanium in the layer of silicon germanium.

Germanium enrichment may also be obtained by means of thermal oxidation. For example, a deposition of 1 nm of oxide and oxidation thermal annealing (OTA) are carried out for example at a temperature between 900° C. and 1100° C. and for a period of between 5 seconds and 40 seconds.

In a variant, enrichment at a lower temperature can be carried out in order to avoid undesired diffusion of dopants in the structure. The document “Kinetics and Energetics of Ge Condensation in SiGe Concentration” Journal of Physical Chemistry 2015, 119, 24606-24613, provides for example for a dry thermal oxidation carried out at a temperature of around 750° C. for a period of 8 hours in order to transform a thickness of silicon of 4 nm into silicon germanium of 50% in atomic proportion.

The oxidation conditions, in particular the temperature and duration, can be adapted so as to carry out only partial enrichment of the second bars 5a, 5b, 5c, and thus preserve a silicon core. The composition of the germanium-enriched thickness may be such as to have a germanium concentration gradient such that the germanium concentration increases on approaching the core of the bars. The germanium enrichment by oxidation leads to the formation of a surface oxide layer that is removed once the germanium condensation is complete.

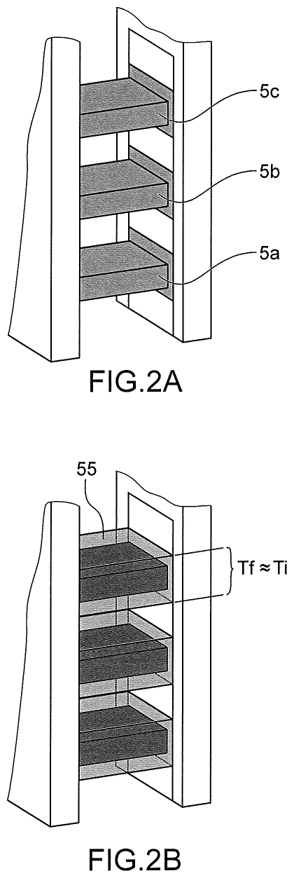

A particular embodiment illustrated in FIGS. 2A-2B provides for a thinning of the second bars 5a, 5b, 5c before carrying out the growth of semiconductor material 55 around these bars 5a, 5b, 5c. The thinning can be carried out for example by etching, for example using ammonia, in accordance with a dosage according to the surrounding materials, or by oxidation of the bars and then removal of the oxidised layer, for example using dilute HF. A succession of sequences each comprising the oxidation and removal of an oxidised layer can be carried out.

Once the thinning of the second bars 5a, 5b, 5c has been carried out, the epitaxial growth of material 55 can be carried out. It is possible to carry out a growth of a thickness of material 55 corresponding substantially to the thickness removed by thinning of the second bars 5a, 5b, 5c. In this way bars 5a, 5b, 5c surrounded by semiconductor material 55, the thickness Tf of which corresponds precisely to the thickness Ti of the second bars 5a, 5b, 5c are obtained.

As in the previous example embodiment, it is then also possible to carry out a germanium enrichment of the second bars 5a, 5b, 5c.

1. A method for producing a semiconductor structure for a transistor, with semiconductor bars disposed one above the other and able to form at least one transistor channel structure, the method comprising:
a) providing, on a support, a stack comprising an alternation of one or more first bars made from sacrificial material, in particular a first semiconductor material, and one or more second bars based on a given second semiconductor material, said stack being covered with a so-called dummy bar made from a given material, advantageously dielectric, different from the sacrificial material and the second semiconductor material, the dummy bar being arranged on a given bar among said first bars, said given bar being disposed at the top of said stack,
b) forming a masking with an opening revealing central portions of said bars in said stack covered with a central portion of said dummy bar,
c) removing in said opening the central portion of the first bars by selective etching of the sacrificial material vis-à-vis said second semiconductor material and the given material of said dummy bar, then
d) growing a semiconductor material on the second bars while during this growth keeping said central portion of said dummy bar.

2. The method according to claim 1, wherein the semiconductor material that is grown on the second bars has a mesh parameter different from that of the second semiconductor material.

3. The method according to claim 2, wherein said semiconductor material that is grown is based on germanium and wherein, after the step d) of growth of semiconductor material, at least one thermal annealing is carried out so as to diffuse germanium in said second bars.

4. The method according to claim 2, wherein said semiconductor material that is grown is based on germanium and wherein, after the step d) of growth of semiconductor material, a gate is formed on regions of semiconductor material preserved around the second bars.

5. The method according to claim 1, wherein the masking is formed by insulating spacers and an encapsulation layer on either side of an assembly formed by a sacrificial gate and insulating spacers against this sacrificial gate, the opening being formed by removal of the sacrificial gate arranged between the insulating spacers.

6. The method according to claim 5, wherein the method further comprises, prior to the formation of the opening, steps of:
production of the sacrificial gate on the stack,
formation of insulating spacers on either side of the sacrificial gate,
removal of the stack on either side of the assembly formed by the sacrificial gate and the spacers.

7. The method according to claim 6, wherein the method further comprises, after removal of said stack on either side of said assembly formed by the sacrificial gate and the spacers:
selective removal of end portions of the first bars so as to reduce the length thereof and to release spaces on either side of end regions of the first bars,
formation of internal spacers made from dielectric material in said spaces.

8. The method according to claim 7, further comprising, after the formation of the internal spacers and prior to the formation of the opening, steps of:
formation of the source and drain regions,
formation of at least encapsulation layer on the source and drain regions, the encapsulation layer being arranged so as to reveal the sacrificial gate.

9. The method according to claim 1, wherein, after the step c) of selective etching and prior to the step d) of growth of semiconductor material on the second bars: the method further comprises at least one thinning of the central portion of the second bars.

10. The method according to claim 9, wherein the central portion of the second bars is thinned by a given thickness during said thinning, the semiconductor material formed by growth on the second bars having a thickness substantially equal to the given thickness.

11. The method according to claim 1, wherein the stack of bars is formed at step a) or prior to step a) by etching a stack of semiconductor layers, the dummy bar serving as an etching mask during the etching of said stack of semiconductor layers.

12. The method according to claim 1, wherein the dummy bar has dimensions, in particular a width, similar or equal to the dimensions, in particular to the width, of the second bars.

13. The method according to claim 1, wherein the dummy bar is based on SiN or SiBCN.

14. The method according to claim 1, wherein the first semiconductor material is based on SiGe and the second semiconductor material is Si.
